(19) United States
(12) Patent Application Publication
(10) Pub. No.: US 2007/0269972 A1
(43) Pub. Date: Nov. 22, 2007

(54) Method of manufacturing a semiconductor device

(75) Inventors: Yoshiyuki Kawashima, Tokyo (JP); Yasushi Ishii, Tokyo (JP); Koichi Toba, Tokyo (JP); Satoru Machida, Tokyo (JP); Takashi Hashimoto, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/797,588

(22) Filed: May 4, 2007

(30) Foreign Application Priority Data
May 22, 2006 (JP) 2006-141460

(51) Int. Cl. H01L 21/44

(52) U.S. Cl. 438/597

(57) ABSTRACT

Provided is a method of manufacturing a semiconductor device having an ONO film composed of a bottom silicon oxide film, a silicon nitride film and a top silicon oxide film over a substrate. The top silicon oxide film of the ONO film is formed in the following manner. A silicon oxide film is formed over the silicon nitride film, and then a hydrogen gas and an oxygen gas are reacted over the silicon nitride film by heating the silicon nitride film (substrate) while reducing the pressure from the atmospheric pressure to grow the silicon oxide film into the top silicon oxide film. According to the present invention, a silicon oxide film having good uniformity and fewer defects can be formed over a silicon-containing underlayer.

### CROSS-REFERENCE TO RELATED APPLICATIONS

The disclosure of Japanese Patent Application No. 2006-141460 filed on May 22, 2006 including the specification, drawings and abstract is incorporated herein by reference in its entirety.

### BACKGROUND OF THE INVENTION

The present invention relates to a manufacturing technology of a semiconductor device, in particular, a technology effective when applied to the manufacture of a semiconductor device having a nonvolatile memory.

As one of nonvolatile memories by which data can be electrically erased and programmed (Electrically Erasable and Programmable Read Only Memory), a split gate memory cell structure using an ONO (Oxide Nitride Oxide) film composed of a bottom silicon oxide film, a silicon nitride film, and a top silicon oxide film is known. The silicon nitride film of this ONO film will serve as a layer for accumulating charges therein (charge storage layer).

The split gate memory cell is equipped with a control gate formed over the main surface of a semiconductor substrate via a gate insulating film and a memory gate electrically isolated, via an ONO film formed over one of the side walls of the control gate and over the main surface of the semiconductor substrate, from the control gate and semiconductor substrate.

A split gate MONOS (Metal Oxide Nitride Oxide Semiconductor) nonvolatile memory composed of a control gate and a memory gate is disclosed in Japanese Unexamined Patent Publication No. 2006-019373.

### SUMMARY OF THE INVENTION

For example, in an electrode (gate) formed over the main surface of a semiconductor substrate via an insulating film such as a silicon oxide film, the insulating film is required to have good uniformity and have fewer defects in order to generate a uniform electric field in the insulating film when a voltage is applied to the electrode.

Also in a nonvolatile memory, an insulating film constituting a memory cell is required to have good uniformity and have fewer defects. A nonvolatile memory must retain programmed data for a long period of time (for example, 10 years or greater). In an MONOS nonvolatile memory, recording of data is performed by accumulating electrons or holes in a silicon nitride film which is a charge storage layer and thereby increasing or decreasing a threshold voltage (Vth). The electrons or holes accumulated in the silicon nitride film however gradually leak, via the top silicon oxide film on the memory gate side or the bottom silicon oxide film on the semiconductor substrate side, into the memory gate or semiconductor substrate with the passage of time, leading to a change in the threshold voltage (Vth). Leakage of charges in such a manner finally results in loss of data. In order to prevent such leakage of charges in a nonvolatile memory, it is necessary to use a film having good uniformity and fewer defects as the top silicon oxide film and the bottom silicon oxide film.

The top silicon oxide film of the MONOS nonvolatile memory sometimes has, as explained later referring to FIGS. 18 and 19, poor uniformity and has many defects. FIGS. 18(a) and (b) illustrate the formation of a top silicon oxide film 103 by ISSG oxidation, in which FIG. 18(a) is a diagram before formation and FIG. 18(b) is a diagram after formation. FIGS. 19(a) and (b) illustrate the formation of a top silicon oxide film 103 by CVD in which FIG. 19(a) is a diagram before formation and FIG. 19(b) is a diagram after formation. The bottom silicon oxide film 101 can be obtained by oxidation of a semiconductor substrate made of silicon so that it has a good uniformity and fewer defects.

When the top silicon oxide film 103 is formed by ISSG (In-Situ Steam Generation) oxidation, the top silicon oxide film 103 is formed by direct oxidation of a silicon nitride film 102 which is an underlying film. Described specifically, a hydrogen gas and an oxygen gas are reacted over the silicon nitride film 102 (semiconductor substrate) by heating the silicon nitride film while reducing the pressure from the atmospheric pressure, whereby the top silicon oxide film 103 is formed by the growth of a silicon oxide film. As illustrated in FIG. 18, however, presence of a foreign matter 104 on the silicon nitride film 102 prior to the formation of the top silicon oxide film 103 disturbs smooth growth of the silicon oxide film at that portion and the silicon oxide film thus obtained inevitably has poor uniformity and has a defect at that portion.

When the top silicon oxide film 103 is formed by CVD (Chemical Vapor Deposition), the top silicon oxide film 103 is deposited over the silicon nitride film 102 which is an underlying film. As illustrated in FIG. 19, even if a foreign matter 104 is present on the silicon nitride film 102, the top silicon oxide film 103 thus formed has a certain film thickness. A film formed by CVD is however usually inferior in evenness of the film and moreover, incorporation of a foreign matter 105 during the film deposition deteriorates the reliability of the film.

It is possible to remove a foreign matter on the silicon nitride film by cleaning or the like, but an oxidizing apparatus or CVD apparatus has at least a certain level of cleanliness and there is a possibility of cleaning causing adhesion of another foreign matter to the silicon nitride film or causing a change in the surface condition, thereby changing the properties.

As described above, the top silicon oxide film has poor uniformity and has many defects because it is formed by the oxidation of a silicon nitride film or deposition of a silicon oxide film by CVD. Use of a top silicon oxide film with poor uniformity and many defects for a nonvolatile memory facilitates leakage of charges stored in the silicon nitride film (charge storage layer) from a thin portion or defect of the top silicon oxide film, leading to deterioration in the data retention properties of the memory.

An object of the present invention is to provide a technology capable of forming, over a silicon-containing underlayer, a silicon oxide film with good uniformity and fewer defects.

The above-described and the other objects and novel features of the present invention will be apparent from the description herein and accompanying drawings.

The typical inventions, of the inventions disclosed by the present application, will be summarized as follows.

In the present invention, there is provided a method of manufacturing a semiconductor device, which comprises forming a silicon oxide film over a silicon-containing underlayer (for example, a silicon nitride film) by CVD, and reacting a hydrogen gas and an oxygen gas over the underlayer by heating the underlayer while reducing the pressure from the atmospheric pressure to cause the growth of the silicon oxide film.

Advantages available from the typical inventions, of the inventions disclosed by the present application, will next be described briefly.

The present invention makes it possible to form, over a silicon-containing underlayer, a silicon oxide film having good uniformity and fewer defects.

### BRIEF DESCRIPTION OF THE DRAWINGS

FIG. 1 is a fragmentary cross-sectional view illustrating a semiconductor device according to Embodiment 1 of the present invention;

FIG. 2 is an equivalent circuit diagram of the semiconductor device illustrated in FIG. 1;

FIG. 3 is a fragmentary cross-sectional view which schematically illustrates the semiconductor device according to Embodiment 1 of the present invention during a manufacturing step thereof;

FIG. 4 is a fragmentary cross-sectional view which schematically illustrates the semiconductor device during a manufacturing step following that of FIG. 3;

FIG. 5 is a fragmentary cross-sectional view which schematically illustrates the semiconductor device during a manufacturing step following that of FIG. 4;

FIG. 6 is a fragmentary cross-sectional view which schematically illustrates the semiconductor device during a manufacturing step following that of FIG. 5;

FIG. 7 is a fragmentary cross-sectional view which schematically illustrates the semiconductor device during a manufacturing step following that of FIG. 6;

FIG. 8 is a fragmentary cross-sectional view which schematically illustrates the semiconductor device during a manufacturing step following that of FIG. 7;

FIG. 9 is a fragmentary cross-sectional view which schematically illustrates the semiconductor device during a manufacturing step following that of FIG. 8;

FIG. 10 is a fragmentary cross-sectional view which schematically illustrates the semiconductor device during a manufacturing step following that of FIG. 9;

FIG. 11 is a fragmentary cross-sectional view which schematically illustrates the semiconductor device during a manufacturing step following that of FIG. 10;

FIG. 12 is a fragmentary cross-sectional view which schematically illustrates the semiconductor device during a manufacturing step following that of FIG. 11;

FIGS. 13(a) and 13(b) are schematic views of the formation step of an ONO film, in which FIG. 13(a) illustrates a step by CVD and FIG. 13(b) illustrates a step by ISSG oxidation;

FIG. 14 is a schematic view illustrating the relationship between the oxidation time and thickness of an oxide film in ISSG oxidation;

FIG. 15 is a fragmentary cross-sectional view illustrating a semiconductor device according to Embodiment 2 of the present invention;

FIG. 16 is a fragmentary cross-sectional view illustrating a semiconductor device according to Embodiment 3 of the present invention;

FIG. 17 is a fragmentary cross-sectional view illustrating a semiconductor device according to Embodiment 4 of the present invention;

FIGS. 18(a) and 18(b) are schematic views illustrating a manner how a top silicon oxide film is formed by ISSG oxidation, in which FIG. 18(a) is a view before formation and FIG. 18(b) is a view after formation; and

FIGS. 19(a) and 19(b) are schematic views illustrating a manner how a top silicon oxide film is formed by CVD, in which FIG. 19(a) is a view before formation and FIG. 19(b) is a view after formation.

### DETAILED DESCRIPTION OF THE INVENTION

The term “ISSG (In-Situ Steam Generation) as used herein means an oxidation process in which with hydrogen and oxygen introduced in a low-pressure reaction chamber, an oxidation reaction is caused directly on the surface of a heated semiconductor substrate. A single-wafer rapid heating apparatus is used for this heating and the semiconductor substrate (semiconductor wafer) is heated by exposing the upper surface thereof to a lamp light. This ISSG oxidation employing ordinary dry oxidation has an increased oxidation power so that it enables oxidation of the surface of a relatively stable silicon nitride film. The oxidation power is presumed to increase because under a low pressure state, a chemical active species (for example, oxygen radical) reaches the surface of a substrate before it is inactivated, and causes silicon dissociation on the surface of the substrate, whereby a reaction between Si and oxygen occurs.

Embodiments of the present invention will hereinafter be described based on accompanying drawings. In all the drawings for describing the below-described embodiments, members having like function will be identified by like reference numerals and overlapping descriptions will be omitted.

### Embodiment 1

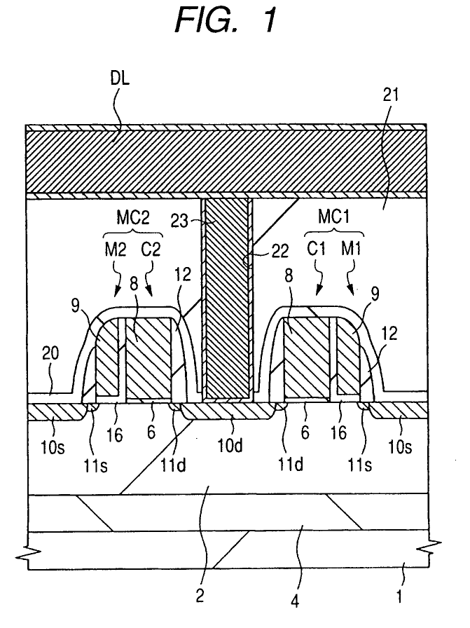

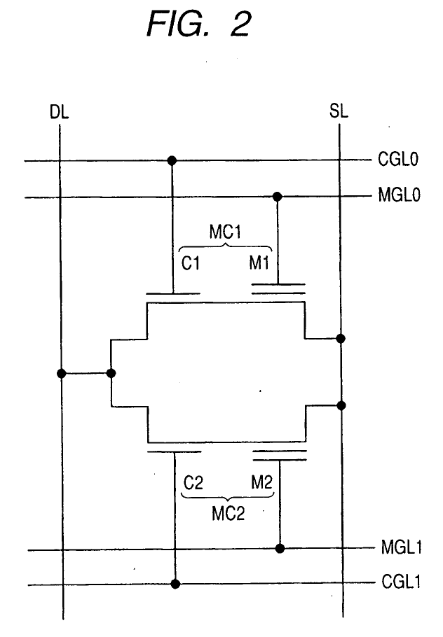

FIG. 1 is a fragmentary cross-sectional view illustrating an MONOS (Metal Oxide Nitride Oxide Semiconductor) nonvolatile memory according to this Embodiment; and FIG. 2 is an equivalent circuit diagram of the MONOS nonvolatile memory illustrated in FIG. 1. In FIGS. 1 and 2, two memory cells (MC1 and MC2) arranged adjacent to each other are shown.

The memory cell MC1 of the MONOS nonvolatile memory is formed over a p well 2 of a semiconductor substrate (which will hereinafter be called “substrate” simply) made of a p type single crystal silicon substrate. The p well 2 is electrically isolated from the substrate 1 via an n buried layer 4 for well isolation so that a desired voltage can be applied to the p well.

The memory cell MC1 is composed of a control transistor Cl and a memory transistor M1. The gate electrode (control gate 8) of the control transistor C1 is made of an n type polysilicon film and is formed over a gate insulating film 6 made of a silicon oxide film. The gate electrode (memory gate 9) of the memory transistor M1 is made of an n type polysilicon film and is arranged over one of the sidewalls of the control gate 8. This memory gate 9 is electrically isolated from the control gate 8 and p well 2 via an ONO film 16 having an L-shaped cross-section composed of a portion formed over one of the sidewalls of the control gate 8 and the other portion formed over the p well 2. The ONO film 16 comprises two silicon oxide films and a silicon nitride film formed therebetween. Upon data programming, hot electrons generated in a channel region are injected into the ONO film 16 and caught by a trap in the silicon nitride film.

In the p well 2 in the vicinity of the control gate 8, an n⁺ type semiconductor region (drain region) 10d functioning as a drain region of the memory cell MC1 is formed, while in the p well 2 in the vicinity of the memory gate 9, an n⁺ type semiconductor region (source region) 10s functioning as a source region of the memory cell MC1 is formed.

In the p well 2 in a region adjacent to the n⁺ type semiconductor region (drain region) 10d, an n⁻ type semiconductor region lid having a lower impurity concentration than the n⁺ type semiconductor region (drain region) 10d is formed. In other words, the n⁻ type semiconductor region lid which is a lightly doped diffusion layer and the n⁺ type semiconductor region (drain region) 10d which is a heavily doped diffusion layer are formed. The n type semiconductor region 11d is an extension region for relaxing the high electric field at the end of the n⁺ type semiconductor region (drain region) 10d and imparting the control transistor C1 with an LDD (Lightly Doped Drain) structure.

In the p well 2 in a region adjacent to the n⁺ type semiconductor region (source region) 10s, an n⁻ type semiconductor region 11s having a lower impurity concentration than the n⁺ type semiconductor region (source region) 10s is formed. In other words, the n⁻ type semiconductor region 11s which is a lightly doped diffusion layer and the n⁺ type semiconductor region (source region) 10s which is a heavily doped diffusion layer are formed. The n⁻ type semiconductor region 11s is an extension region for relaxing the high electric field at the end of the n⁺ type semiconductor region (source region) 10s and imparting the memory transistor M1 with an LDD (Lightly Doped Drain) structure.

A sidewall spacer 12 made of a silicon oxide film is formed over the other one of the sidewalls of the control gate 8 and one of the sidewalls of the memory gate 9. These sidewall spacers 12 are utilized for the formation of the n⁺ type semiconductor region (drain region) 10d and n⁺ type semiconductor region (source region) 10s.

A data line DL is formed above the memory cell MC1 via a silicon nitride film 20 and a silicon oxide film 21. The data line DL is electrically coupled to the n⁺ type semiconductor region (drain region) 10d via a plug 23 in a contact hole 22 formed above the n⁺ type semiconductor region (drain region) 10d. The data line DL is made of a metal film having an aluminum alloy as a main component, while the plug 23 is made of a metal film having tungsten as a main component.

As illustrated in FIG. 2, the control gate 8 of the control transistor C1 is coupled to a control gate line CGL0, while the memory gate 9 of the memory transistor M1 is coupled to a memory gate line MGL0. The source region 10s is coupled to a source line SL and a desired voltage is applied to the p well 2 through a power wire which is not illustrated.

The memory cell MC2 adjacent to the memory cell MC1 has the same structure as that of the MC1 and has a drain region 10d in common with the memory cell MC1. As described above, this drain region 10d is coupled to the data line DL. These two memory cells MC1 and MC2 are arranged symmetrically with the common drain region 10d therebetween. A control gate 8 of a control transistor C2 is coupled to a control gate line CGL1, while a memory gate 9 of a memory transistor M2 is coupled to a memory gate line MGL1. A source region 10s is coupled to the source line SL.

Each of programming, erasing and reading operations when the memory cell MC1 is used as a selected memory cell will next be explained. Injection of electrons into the silicon nitride film of the ONO film 16 or into the interface between the silicon nitride film and silicon oxide film is defined as “programming”, while injection of holes is defined as “erasing”.

For programming, hot electron programming system which is so-called “source side injection system” is employed. Upon programming, voltages of 1.5V, 12V, 6V, 1V and 0V are applied to the control gate 8, memory gate 9, n⁺ type semiconductor region (source region) 10s, n⁺ type semiconductor region (drain region) 10d and p well 2, respectively. By this voltage application, hot electrons are generated in a region which is within a channel region formed between the n⁺ type semiconductor region (source region) 10s and n⁺ type semiconductor region (drain region) 10d and is near the midway between the control gate 8 and memory gate 9 and they are injected into the silicon nitride film of the ONO film 16 or interface between the silicon nitride film and silicon oxide film. The electrons thus injected are caught in a trap in the silicon nitride film or at the interface between the silicon nitride film and silicon oxide film, leading to an increase in the threshold voltage of the memory transistor M1.

For erasing, a BTBT (Band-To-Band Tunneling) hot hole injection erase system can be employed. Upon erasing, voltages of 0V, 6V, 6V, 0V and 0V are applied to the control gate 8, memory gate 9, n⁺ type semiconductor region (source region) 10s, n⁺ type semiconductor region (drain region) 10d and p well 2 of a selected memory cell, respectively. Holes (positive holes) are generated by the BTBT (Band-To-Band Tunneling) phenomenon to cause field acceleration, whereby the holes are injected into the ONO film 16. The holes thus injected are caught in a trap in the silicon nitride film or at the interface between the silicon nitride film and silicon oxide film, causing a reduction in the threshold voltage of the memory transistor M1.

Upon reading, voltages of 1.5V, 1.5V, 0V, 1.5V and 0V are applied to the control gate 8, memory gate 9, n⁺ type semiconductor region (source region) 10s, n⁺ type semiconductor region (drain region) 10d and p well 2, respectively. By setting the voltage to be applied to the memory gate 9 to a value between the threshold voltage of the memory transistor M1 in a program state and the threshold voltage of the memory transistor M1 in an erase state, the program state is discriminated from the erase state.

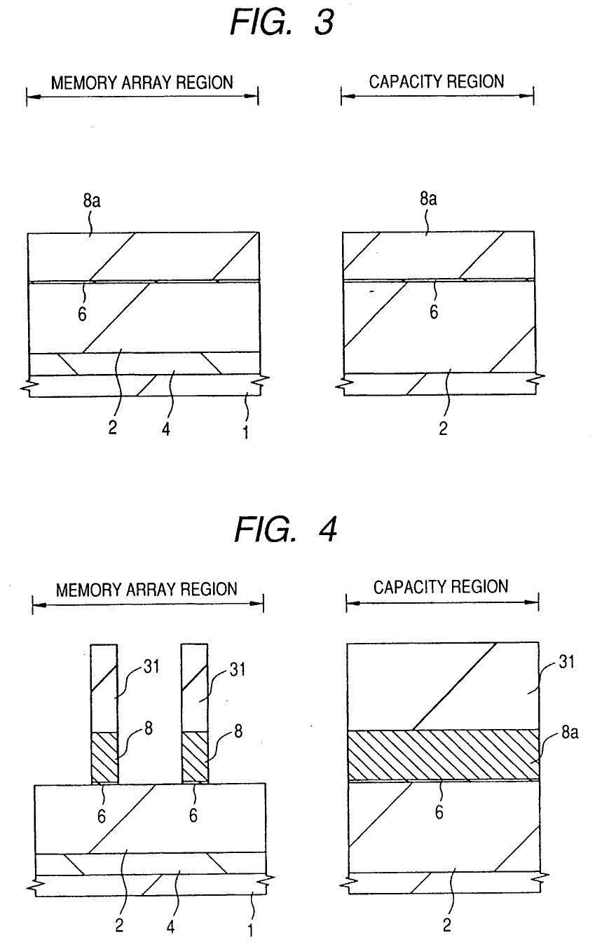

A manufacturing process of the MONOS nonvolatile memory will next be described in the order of steps based on FIGS. 3 to 14. The MONOS nonvolatile memory has, for example, a sense amplifier, column decoder, row decoder and booster circuit as a peripheral circuit thereof. In FIGS. 3 to 12, a memory array region in which a memory cell is formed and a capacity region in which a capacitive element (PIP capacity) is formed are illustrated.

As illustrated in FIG. 3, an n buried layer 4 and p well 2 are formed over the main surface of the substrate 1 in the memory array region and a p well 2 is formed over the main surface of the semiconductor substrate 1 in the capacity region, each by using a well known manufacturing process. The substrate 1 is then thermally oxidized to form a gate insulating film 6 made of silicon oxide over the surface of the p well 2. The gate insulating film 6 is formed in both the memory array region and the capacity region. An electrode material film is then formed over the gate insulating film 6. Described specifically, after deposition of an undoped 16 polysilicon film 8a having a film thickness of about 250 nm over the substrate 1 by CVD, an impurity (phosphorus or arsenic) is ion-implanted into the undoped polysilicon film 8a in the memory array region and capacity region, whereby the undoped polysilicon film 8a in these regions is converted into an n-type polysilicon film 8a. When the impurity is phosphorus, the dose thereof is about 6×10¹⁵ atoms/cm². The polysilicon film 8a is an electrode material film constituting the control gate 8 of the memory cell and a lower electrode 8A of the PIP capacity.

If necessary, the undoped polysilicon film 8a can be converted into a p type polysilicon film. In this case, the undoped polysilicon film 8a over the p well 2 is covered with a photoresist film, and an impurity (boron or boron fluoride) is ion-implanted into the undoped polysilicon film 8a of predetermined regions, whereby the undoped polysilicon film 8a in these regions is converted into a p type polysilicon film.

As illustrated in FIG. 4, with a photoresist film 31 as a mask, the polysilicon film 8a in the memory array region is patterned to form a control gate 8 made of the polysilicon film 8a. By this patterning, the gate insulating film 6 is left below the control gate 8.

The control gate 8 formed in the memory array region has a gate length of about 180 nm. When the gate length of the control gate 8 is as small as about 180 nm, the aspect ratio (a ratio of gate height to gate length) of the control gate 8 exceeds 1. When the control gate 8 having such a high aspect ratio is formed after formation of a memory gate 9, there is a difficulty in processing the control gate 8. In this Embodiment, therefore, the control gate 8 is formed, followed by the formation of the memory gate 9. This makes it possible to form the memory gate 9 having a smaller gate length than the control gate 8 over the sidewall of the control gate 8.

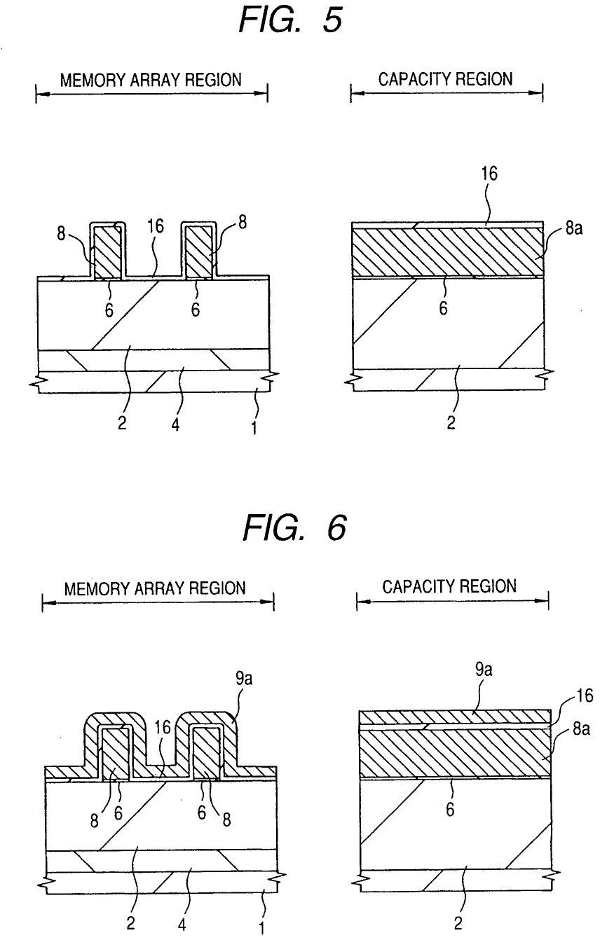

As illustrated in FIG. 5, an ONO film 16 is then formed over the substrate 1. The ONO film 16 has a three-layer film composed of a bottom silicon oxide film formed over the main surface of the substrate 1, a silicon nitride film formed over the bottom silicon oxide film, and a top silicon oxide film formed over the silicon nitride film.

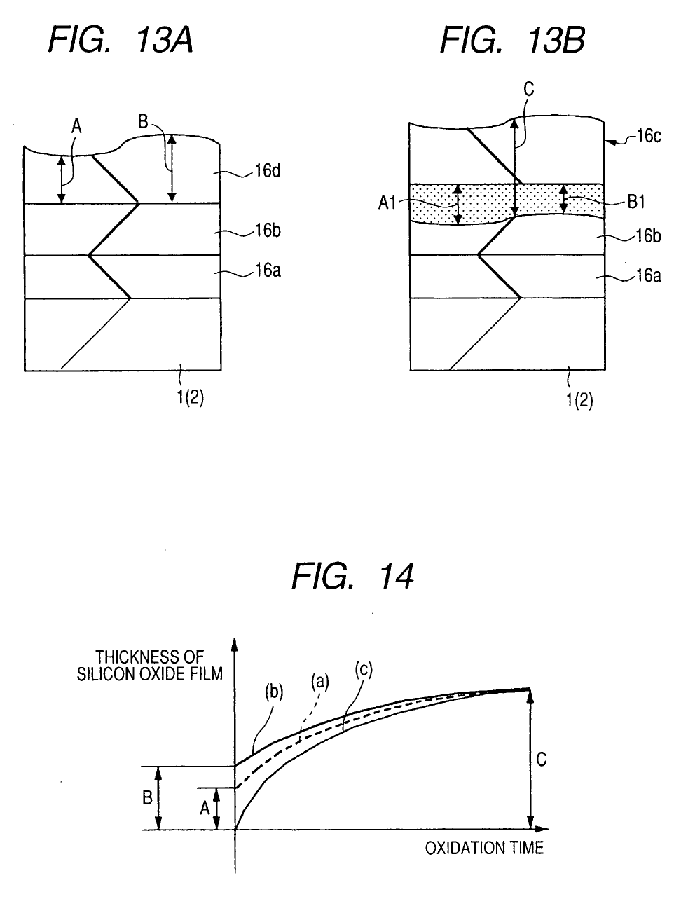

The formation of the ONO film 16 will next be described specifically with reference to FIGS. 13 and 14. First, as illustrated in FIG. 13(a), after formation of a bottom silicon oxide film 16a made of, for example, SiO₂ and having a thickness of about 5 nm over the substrate 1 (p well 2) by ISSG oxidation, a silicon nitride film 16b made of, for example, SiN and having a thickness of about 10 nm is formed over the bottom silicon oxide film 16a. The bottom silicon oxide film 16a is obtained by ISSG oxidation with the substrate 1 made of a single crystal silicon substrate as an underlayer so that the bottom silicon oxide film 16a has good uniformity and has fewer defects.

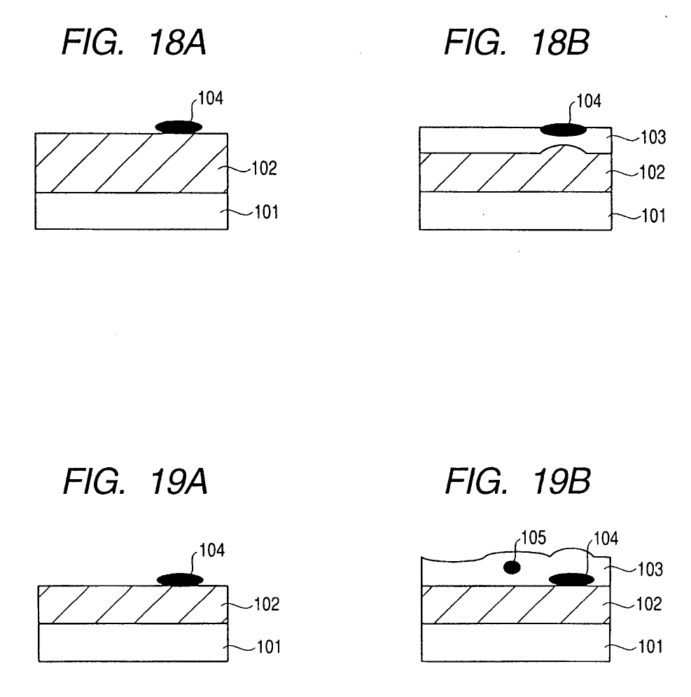

With the silicon nitride film 16b as an underlayer film, a silicon oxide film 16d made of, for example, SiO₂ is formed over the silicon nitride film 16b by CVD. When the top silicon oxide film 103 is formed by direct ISSG oxidation of the silicon nitride film 102 having a foreign matter thereon (refer to FIG. 18), its film thickness in a region in which the foreign matter is present becomes thin. Since this silicon oxide film 16d is formed by CVD, on the other hand, there occurs no thinning of a film in a region in which a foreign matter is present and the film can have a predetermined uniform film thickness. The silicon oxide film 16d however has an uneven film thickness (Film thickness A<Film thickness B) because it is obtained by deposition by CVD.

As illustrated in FIG. 13(b), the silicon oxide film 16d is then grown into the top silicon oxide film 16c by ISSG oxidation. Described specifically, by heating the silicon nitride film 16b which will be an underlayer film, for example, at from 900 to 1000° C. while reducing the pressure from atmospheric pressure to about 7.5 Torr, from 1 to 30 atom % of a hydrogen and oxygen gas mixture is reacted over the silicon nitride film 16b for from 60 to 100 seconds, whereby the silicon oxide film 16d is grown into the top silicon oxide film 16c. This heating also serves to densify the silicon oxide film 16d.

When the silicon oxide film 16d formed by CVD is grown by ISSG oxidation, an oxidation rate is high at a thin portion of the silicon oxide film 16d and is low at a thick portion of the silicon oxide film 16d. The reason of such a phenomenon will next be described.

As the graph (c) in FIG. 14 shows, ISSG oxidation is characterized in that when the thickness of an oxide film is small, the film formation rate is high and with an increase in the thickness of an oxide film, the film formation rate decreases. The graphs (a) and (b) in FIG. 14 show the film formation rate by ISSG oxidation after the formation of a silicon oxide film by CVD in advance over a film (for example, a silicon nitride film) to be oxidized. They suggest that when the silicon oxide film has been formed by CVD, the film formation rate of an oxide film is small even just before the initiation of the ISSG oxidation. When an oxide film formed by CVD having a smaller thickness (graph (a) in FIG. 14) is compared with that having a greater thickness (graph (b) in FIG. 14), the film formation rate of the former one is high after the oxidation is started. A difference in the thickness between them therefore decreases when the oxidation is continued and at last, it almost disappears. This occurs because a chemical active species (such as oxygen radical) reacts on the silicon nitride film 16b and it must pass through the silicon oxide film 16d.

The oxidation rate is high at a thin portion of the silicon oxide film 16d and low at a thick portion thereof so that the top silicon oxide film 16c can therefore be formed with a substantially uniform thickness C (for example, about 5 nm).

It is also possible, after the formation of the bottom silicon oxide film 16a and before the formation of the silicon nitride film 16b, to subject the bottom silicon oxide film 16a to nitriding treatment in a high-temperature atmosphere containing a nitrogen oxide such as N₂O to segregate nitrogen at the interface between the bottom silicon oxide film 16a and substrate 1. This nitriding treatment improves the hot carrier resistance of the control transistor and memory transistor constituting the memory cell, thereby contributing to the improvement of the properties (such as rewrite properties) of the memory cell. It is also possible, after formation of the control gate 8 before the step of forming the ONO film 16, to ion-implant, into the p well 2 of the memory array region, an impurity for regulating the threshold voltage of the control transistor or an impurity for regulating the threshold voltage of the memory transistor. This makes it possible to optimize the threshold voltage of the control transistor and memory transistor.

A memory gate 9 is then formed over one of the sidewalls of the control gate 8. The memory gate 9 can be formed in the following manner. First, as illustrated in FIG. 6, an n type polysilicon film 9a which is an electrode material film is deposited over the ONO film 16 (substrate 1) by CVD. The impurity (phosphorus or arsenic) concentration of the n type polysilicon film 9a is from about 1×10²⁰ atoms/cm³ to 6×10²⁰ atoms/cm³.

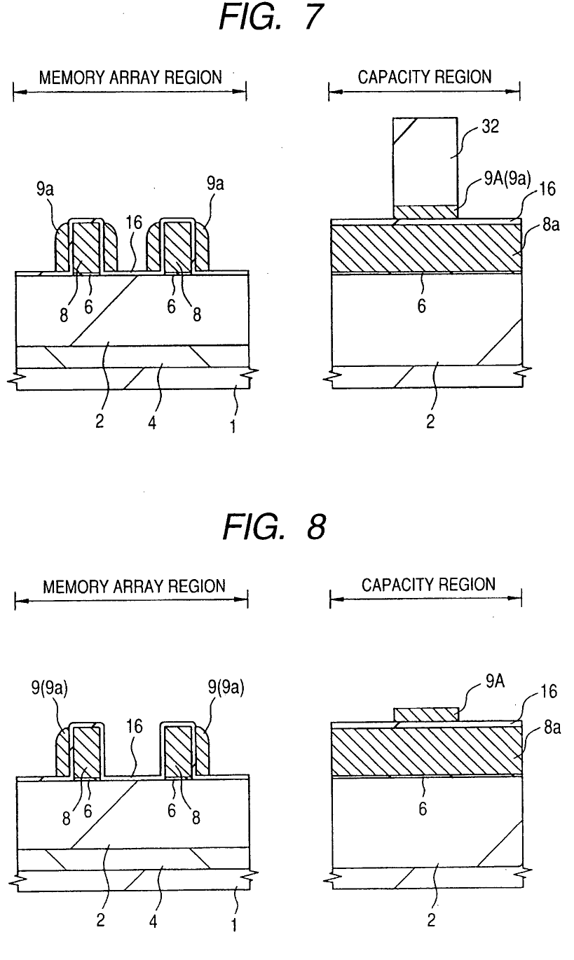

As illustrated in FIG. 7, the polysilicon film 9a is then anisotropically etched, whereby the polysilicon film 9a is left over both sides of the sidewalls of the control gate 8 in the memory array region, while in the capacity region, the polysilicon film 9a is patterned with a photoresist film 32 as a mask to form an upper electrode 9A made of the polysilicon film 9a.

As illustrated in FIG. 8, the polysilicon film 9a is then etched with a photoresist film (not illustrated) covering therewith a portion of the memory array region in which the memory gate is to be formed and the capacity region as a mask, whereby the memory gate 9 made of the polysilicon film 9a is formed over one of the sidewalls of the control gate 8.

The memory gate 9 formed over the sidewall of the control gate 8 has a gate length of about 80 nm and has an aspect ratio (a ratio of a gate height to a gate length) exceeding 1. In this Embodiment, the control gate 8 is formed, followed by the formation of the memory gate 9 so that the memory gate 9 having a smaller gate length and higher aspect ratio than the control gate 8 can easily be formed.

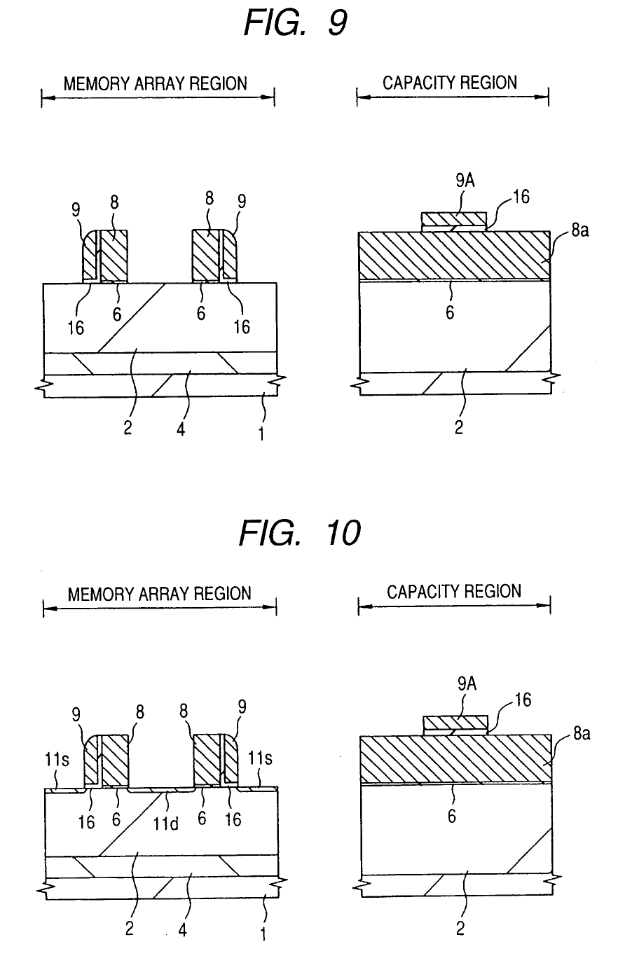

As illustrated in FIG. 9, the top silicon oxide film 16c, silicon nitride film 16b and bottom silicon oxide film 16a constituting the ONO film 16 are etched with hydrofluoric acid and phosphoric acid. By this etching, the ONO film 16 formed in an unnecessary region is removed. In the memory array region, the ONO film 16 remains over one of the sidewalls of the control gate 8 and below the memory gate 9, while in the capacity region, the ONO film 16 remains below the upper electrode 9A.

As illustrated in FIG. 10, with a photoresist film (not illustrated) covering therewith the capacity region as a mask, an impurity (phosphorus or arsenic) is then ion-implanted into a portion of the memory array region to form an n-type semiconductor region 11d and n-type semiconductor region 11s. The n-type semiconductor region lid and n-type semiconductor region 11s are extension regions to impart an LDD structure to the control transistor of the memory cell.

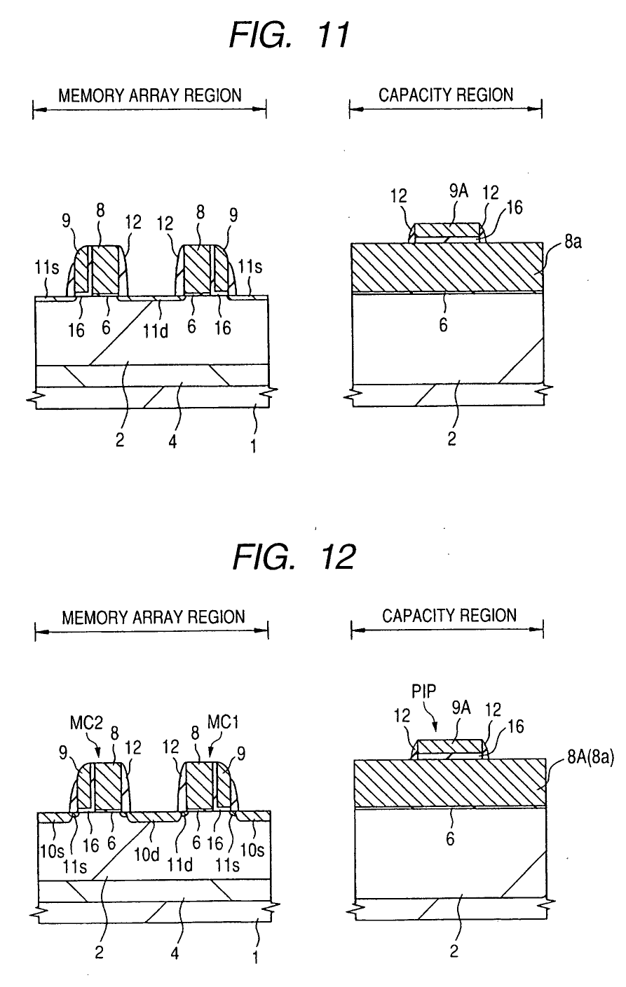

As illustrated in FIG. 11, a sidewall spacer 12 is formed over one of the sidewalls of each of the control gate 8 and memory gate in the memory array region, while sidewall spacers 12 are formed over both sidewalls of the upper electrode 9A in the capacity region. These sidewall spacers 12 are formed by anisotropic etching of a silicon oxide film deposited over the substrate 1 by CVD.

As illustrated in FIG. 12, an impurity (phosphorus or arsenic) is ion-implanted in the memory array region with a photoresist film (not illustrated) as a mask. By this ion implantation, n⁺ type semiconductor region (drain region) 10d and n⁺ type semiconductor region (source region) 10s are formed in the memory array region, whereby a memory cell MC is completed. In the capacity region, a capacitive element PIP having the upper electrode 9A and lower electrode 8A is completed. The resistance of each of the control gate 8 and memory gate 9 can be lowered by forming a silicide layer such as cobalt silicide over the surfaces of the control gate 8, memory gate 9, n⁺ type semiconductor region (source region) 10s and n⁺ type semiconductor region (drain region) 10d of the memory cell MC.

### Embodiment 2

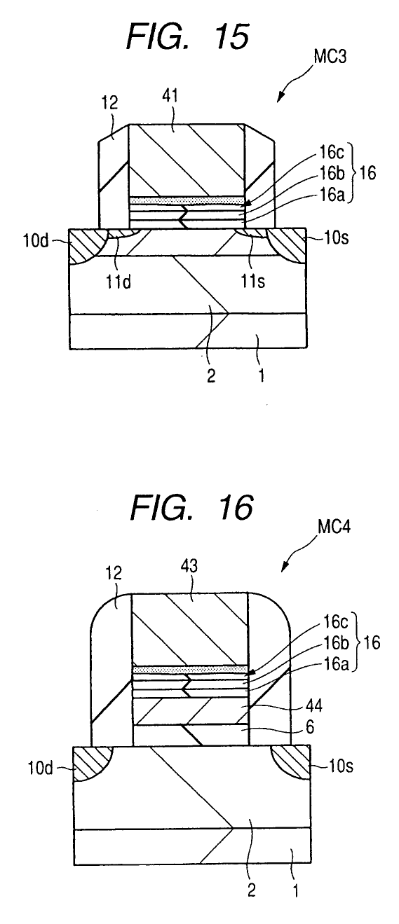

FIG. 15 is a fragmentary cross-sectional view illustrating an MONOS nonvolatile memory according to this Embodiment. This memory cell MC3 has a memory gate 41 formed over the main surface of a substrate 1 made of a p type single crystal silicon substrate via an ONO film 16. The ONO film 16 is composed of a bottom silicon oxide film 16a formed over the main surface of the substrate 1, a silicon nitride film 16b formed over the bottom silicon oxide film, and a top silicon oxide film 16c formed over the silicon nitride film 16b. The memory gate 41 is made of an n type polysilicon film, which is an electrode material film, formed over the ONO film 16.

The ONO film 16 is formed in the following manner. First, after formation of the bottom silicon oxide film 16a made of, for example, SiO₂ over the substrate 1 by ISSG oxidation, the silicon nitride film 16b made of, for example, SiN is formed over the bottom silicon oxide film 16a by CVD. Then, after formation of a silicon oxide film made of, for example, SiO₂ over the silicon nitride film 16b which is an underlayer film by CVD, a mixture of a hydrogen gas and an oxygen gas is reacted over the silicon nitride film 16b by heating the silicon nitride film 16b while reducing the pressure from the atmospheric pressure to grow the silicon oxide film into the top silicon oxide film 16c. This heating also serves to densify the silicon oxide film formed by CVD.

Even if the silicon oxide film formed by CVD has poor uniformity and has defects, the silicon oxide film 16c thus formed has good uniformity and has fewer defects.

### Embodiment 3

FIG. 16 is a fragmentary cross-sectional view illustrating a floating gate nonvolatile memory according to this Embodiment. A memory cell MC4 of this memory has an ONO film 16, which is formed over a floating gate 42 for accumulating charges therein via a gate insulating film 6 over a substrate 1 made of a p type single crystal silicon substrate 1, and a select gate 43 formed over the ONO film 16. The ONO film 16 is composed of a bottom silicon oxide film 16a formed over the main surface of the substrate 1, a silicon nitride film 16b formed over the bottom silicon oxide film, and a top silicon oxide film 16c formed over the silicon nitride film 16b. The select gate 43 is made of an n type polysilicon film, which is an electrode material film, formed over the ONO film 16, while the floating gate 42 is made of an n type polysilicon film, which is an electrode material film, formed over the gate insulating film 6.

The ONO film 16 is formed in the following manner. First, after formation of the bottom silicon oxide film 16a made of, for example, SiO₂ over the substrate 1 by ISSG oxidation, the silicon nitride film 16b made of, for example, SiN is formed over the bottom silicon oxide film 16a by CVD. Then, after formation of a silicon oxide film made of, for example, SiO₂ over the silicon nitride film 16b which is an underlayer film by CVD, a mixture of a hydrogen gas and an oxygen gas is reacted over the silicon nitride film 16b by heating the silicon nitride film 16b while reducing the pressure from the atmospheric pressure to grow the silicon oxide film into the top silicon oxide film 16c. This heating also serves to densify the silicon oxide film formed by CVD.

Even if the silicon oxide film formed by CVD has poor uniformity and has defects, the silicon oxide film 16c thus formed has good uniformity and has fewer defects.

### Embodiment 4

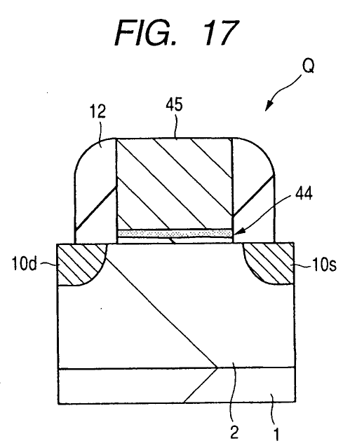

FIG. 17 is a fragmentary cross-sectional view illustrating MISFET according to this Embodiment. This MISFET (Q) has a gate 45 formed over the main surface of a substrate 1 made of a p type single crystal silicon substrate via a gate insulating film 44. The gate insulating film 44 is made of a silicon oxide film, while the gate 45 is made of an n type polysilicon film, which is an electrode material film, formed over the gate insulating film 44.

The gate insulating film 44 is formed in the following manner. After formation of a silicon oxide film made of, for example, SiO₂ over the substrate 1 which is an underlayer, by CVD, a mixture of a hydrogen gas and an oxygen gas is reacted over the substrate 1 by heating the substrate 1 while reducing the pressure from the atmospheric pressure to grow the silicon oxide film into the gate insulating film 44. This heating also serves to densify the silicon oxide film formed by CVD.

Even if the silicon oxide film formed by CVD has poor uniformity and has defects, the gate insulating film 44 thus formed has good uniformity and has fewer defects.

The invention made by the present inventors was described specifically based on some embodiments. The present invention is however not limited to or by them. It is needless to say that these embodiments can be modified variously without departing from the scope of the invention.

For example, a silicon nitride (SiN) film is used as a charge storage layer for the ONO film in Embodiments 1 to 3, but a silicon oxynitride (SiON) film may be used instead. In this case, similar advantages to those described in Embodiments of the present application can be brought about.

The present invention is widely used by manufacturers of semiconductor devices.

What is claimed is:

1. A method of manufacturing a semiconductor device including: a silicon-containing underlayer; a first silicon oxide film formed over the underlayer; and an electrode material film formed over the first silicon oxide film, the method comprising the steps of:
(a) forming a second silicon oxide film over the underlayer by CVD;
(b) after the step (a), reacting a hydrogen gas and an oxygen gas over the underlayer by heating the underlayer while reducing the pressure from the atmospheric pressure to grow the second silicon oxide film into the first silicon oxide film; and
(c) forming the electrode material film over the first silicon oxide film.

2. A method of manufacturing a semiconductor device according to claim 1, wherein the second silicon oxide film obtained in the step (a) is densified by the heating in the step (b).

3. A method of manufacturing a semiconductor device according to claim 1,
wherein the semiconductor device is equipped with a memory cell having: a control gate formed over the main surface of the semiconductor substrate via a gate insulating film; an ONO film having a portion formed over one of the sidewalls of the control gate and the other portion formed over the main surface of the semiconductor substrate; and a memory gate which is electrically isolated from the control gate via the portion of the ONO film, electrically isolated from the semiconductor substrate via the other portion of the ONO film and constitutes the split gate together with the control gate,
wherein the ONO film has a bottom silicon oxide film formed over the main surface of the semiconductor substrate, a silicon nitride film formed over the bottom silicon oxide film, and a top silicon oxide film formed over the silicon nitride film,
wherein the silicon nitride film has the underlayer,
wherein the memory gate has the electrode material film, and
wherein the top silicon oxide film has the first silicon oxide film.

4. A method of manufacturing a semiconductor device according to claim 1,
wherein the semiconductor device has, over the main surface of the semiconductor substrate, a capacitive element having a first electrode and a second electrode,
wherein the first electrode has the underlayer,
wherein the second electrode has the electrode material film, and
wherein the first electrode and second electrode have therebetween the first silicon oxide film.

5. A method of manufacturing a semiconductor device according to claim 1,
wherein the semiconductor device is equipped with a memory cell having a memory gate formed over the main surface of the semiconductor substrate via an ONO film,
wherein the ONO film has a bottom silicon oxide film formed over the main surface of the semiconductor substrate, a silicon nitride film formed over the bottom silicon oxide film, and a top silicon oxide film formed over the silicon nitride film,
wherein the silicon nitride film has the underlayer,
wherein the memory gate has the electrode material film, and
the top silicon oxide film has the first silicon oxide film.

6. A method of manufacturing a semiconductor device according to claim 1,
wherein the semiconductor device is equipped with a memory cell having: floating gate formed over the main surface of the semiconductor substrate for accumulating charges via a gate insulating film; an ONO film formed over the floating gate; and a select gate formed over the ONO film,
wherein the ONO film has a bottom silicon oxide film formed over the floating gate, a silicon nitride film formed over the bottom silicon oxide film, and a top silicon oxide film formed over the silicon nitride film,
wherein the silicon nitride film has the underlayer,
wherein the select gate has the electrode material film, and
wherein the top silicon oxide film has the first silicon oxide film.

7. A method of manufacturing a semiconductor device according to claim 1,
wherein the semiconductor device is equipped with MISFET having a gate formed over the main surface of the semiconductor substrate via a gate insulating film,
wherein the semiconductor substrate has the underlayer,
wherein the gate has the electrode material film, and
wherein the gate insulating film has the first silicon oxide film.

8. A method of manufacturing a semiconductor device equipped with a memory cell having: a control gate formed over the main surface of a semiconductor substrate via a gate insulating film; an ONO film having a portion formed over one of the sidewalls of the control gate and the other portion formed over the main surface of the semiconductor substrate; and a memory gate which is electrically isolated from the control gate via the portion of the ONO film, electrically isolated from the semiconductor substrate via the other portion of the ONO film and constitutes a split gate together with the control gate, the method comprising the steps of:
(a) after formation of the gate insulating film over the main surface of the semiconductor substrate and formation of a first electrode material film over the gate insulating film, forming the control gate having the first electrode material film by patterning;
(b) forming a bottom silicon oxide film so as to cover therewith the main surface of the semiconductor substrate, and the sidewalls and upper surface of the control gate;
(c) forming a silicon nitride film over the bottom silicon oxide film;
(d) forming a top silicon oxide film over the silicon nitride film;
(e) forming a second electrode material film over the top silicon oxide film;
(f) patterning the second electrode material film to form the memory gate having the second electrode material film over one of the sidewalls of the control gate; and
(g) removing the top silicon oxide film, silicon nitride film and bottom silicon oxide film from a predetermined region to form the ONO film,
wherein the step (d) further comprises:
(d1) forming a silicon oxide film over the silicon nitride film by CVD; and
(d2) after the step (d1), reacting a hydrogen gas and an oxygen gas over the silicon nitride film by heating the semiconductor substrate while reducing the pressure from the atmospheric pressure to grow the silicon oxide film into the top silicon oxide film.

9. A method of manufacturing a semiconductor device according to claim 8,
wherein the semiconductor device is equipped further with a capacitive element having a first electrode and a second electrode over the main surface of the semiconductor substrate,
wherein the first electrode has the first electrode material film,
wherein the second electrode has the second electrode material film, and
wherein the first electrode and second electrode have, therebetween, the bottom silicon oxide film, the silicon nitride film and the top silicon oxide film.
